(19) United States
(12) Patent Application Publication
(10) Pub. No.: US 2026/0184206 A1
(43) Pub. Date: Jul. 2, 2026

(54) HIGH-POWER CHARGING SYSTEM

(71) Applicant: TMEVNET CO., LTD., Bucheon-si (KR)

(72) Inventor: Hyoung Nam CHO, Seoul (KR)

(73) Assignee: TMEVNET CO., LTD., Bucheon-si (KR)

(21) Appl. No.: 19/026,743

(22) Filed: Jan. 17, 2025

(30) Foreign Application Priority Data
Dec. 27, 2024 (KR) 10-2024-0198735

(51) Int. Cl. B60L 53/302; B60L 53/18; H05K 7/20

(52) U.S. Cl. CPC B60L 53/302; B60L 53/18; H05K 7/20318; H05K 7/20354; H05K 7/20372

(57) ABSTRACT

Proposed is a high-power charging system including a cooling system configured to cool a high-power electric cable for rapid charging of an electric vehicle, the high-power charging system being configured such that a power cable in the form of a bare wire is inserted into a cooling part and is exposed to a refrigerant environment at a low temperature so that cooling of the power cable is realized.

### CROSS REFERENCE TO RELATED APPLICATION

The present application claims priority to Korean Patent Application No. 10-2024-0198735, filed December 27, 2024, the entire contents of which are incorporated herein for all purposes by this reference.

### BACKGROUND

### Technical Field

The present disclosure relates to a high-power charging system including a cooling system configured to cool a high-power electric cable for rapid charging of an electric vehicle. More particularly, the present disclosure relates to a high-power charging system configured such that a power cable in the form of a bare wire is inserted into a cooling part and is exposed to a refrigerant environment at a low temperature so that cooling of the power cable is realized.

### Description of the Related Art

One of technical factors as obstacles in a distribution of an electric vehicle is that a charging time of the electric vehicle is long. Particularly, in a direct current system, when a current is increased for rapid charging in order to reduce the charging time, a high Joule heat is emitted in proportional to the current, so that a cooling technology for managing heat is required. Particularly, since heat generated during charging leads to an increase in electrical resistance, it is important to cool a charging power cable and a connector that are overheated.

In order to cool the overheated power cable, a water-cooled method in which a refrigerant pipe where a refrigerant such as water flows therethrough and circulates in a cable containing a power cable so as to cool the adjacent power cable may be used. In this case, in addition to the pipe containing the power cable, a pipe to which the refrigerant is supplied and a pipe to which the refrigerant is recovered are required to be provided separately, so that there is a problem that not only the pipes occupy an additional volume but also the efficiency of the cooling is reduced.

### Document of Related Art

(Patent Document 1) Korean Patent No. 10-2526967 “ELECTRIC VEHICLE CHARGING CONNECTOR AND ELECTRIC VEHICLE CHARGING ASSEMBLY HAVING THE SAME” (registered on April 25, 2023)

(Patent Document 2) Korean Patent No. 10-2483820 “QUICK-CHAGING COOLING CABLE ASSEMBLY FOR ELECTRIC VEHICLES” (registered on December 28, 2022)

### SUMMARY

Accordingly, the present disclosure has been made keeping in mind the above problems occurring in the related art, and an objective of the present disclosure is to provide a high-power charging system for rapid charging, the high-power charging system having an excellent cooling performance.

According to the present disclosure, there is provided a high-power charging system including: a connector for charging an electric vehicle; a power supply apparatus including a power cable for supplying electricity to the connector; and a cooling system including a cooling part in which a refrigerant that cools the power cable flows, wherein the power cable is inserted inside the cooling part and is exposed to a refrigerant environment at a low temperature.

At this time, the power cable may be provided in the form of a bare wire, and may exchange heat with the refrigerant by being in direct contact with the refrigerant.

Meanwhile, the cooling system may be a closed loop connecting a compressor, a condenser, an expansion valve, and the cooling part to each other, and may include an insulation part at at least one place before or after where the refrigerant flows into the cooling part.

More specifically, the power cable may include a positive electrode cable and a negative electrode cable, wherein the cooling part may include: a positive electrode cable cooling pipe configured to cool the positive electrode cable; a negative electrode cable cooling pipe configured to cool the negative electrode cable; and a connection pipe connecting the positive electrode cable cooling pipe and the negative electrode cable cooling pipe to each other, and wherein the positive electrode cable cooling pipe and the negative electrode cable cooling pipe may be parts of a refrigerant pipe in which the refrigerant flows throughout the cooling system, and the positive electrode cable cooling pipe and the negative electrode cable cooling pipe may be formed of the same material.

In addition, the power cable may include a positive electrode cable and a negative electrode cable, wherein the cooling part may include: a positive electrode cable cooling pipe configured to cool the positive electrode cable; a negative electrode cable cooling pipe configured to cool the negative electrode cable; and a connection pipe connecting the positive electrode cable cooling pipe and the negative electrode cable cooling pipe to each other, and wherein each of the positive electrode cable cooling pipe and the negative electrode cable cooling pipe may be formed of a heat insulation material having a thermal conductivity lower than that of a refrigerant pipe in which the refrigerant flows throughout the cooling system.

In addition, the connection pipe may include an insulation part.

Meanwhile, the power cable may include a positive electrode cable and a negative electrode cable, and the cooling system may be configured as a plurality of cooling systems configured to respectively cool the positive electrode cable and the negative electrode cable.

In addition, the connector may include a power supply terminal configured to be connected to a charging terminal of the electric vehicle, and the cooling part may include a sub-cooling pipe configured to bypass a flow of a part of the refrigerant so as to cool the power supply terminal.

In addition, the refrigerant may be a refrigerant for cryogenic cooling, may be selected from one of R134a, R32, R410A, R404A, R507, 1234yf, and 1234ze, and may undergo a liquid-to-vapor phase transformation through heat-exchange in the cooling part.

In the present disclosure, by inserting the power cable in the form of the bare wire directly into the cooling part, heat-exchange between the power cable and the refrigerant is capable of being rapidly and efficiently performed, so that there is an effect that a rapid charging is capable of being realized as the electrical resistance of the power cable is reduced.

In addition, since the refrigerant in the cooling part uses latent heat that is vaporized through a liquid phase change, the overall efficiency of the cooling system is capable of being increased.

In addition, by adopting a single pipe structure of the cooling part rather than a double structure of a power cable and a refrigerant pipe, there are effects that the configuration of the charging system including the connector is simplified and the weight of the charging system is reduced.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating a basic concept of the present disclosure;

FIG. 2 is a detailed view illustrating a cooling part of the present disclosure;

FIG. 3 is an enlarged view illustrating part A in FIG. 1 in the present disclosure; and

FIG. 4 is a conceptual view illustrating another embodiment of the present disclosure.

### DETAILED DESCRIPTION

Hereinafter, an embodiment of the present disclosure will be described in detail with reference to the accompanying drawings.

Since the present disclosure may be variously changed and have various embodiments, particular embodiments will be exemplified in the drawings and will be described in detail in the detailed description. However, this is not intended to limit the present disclosure to a particular disclosed form. On the contrary, the present disclosure is to be understood to include all various alternatives, equivalents, and substitutes that may be included within the idea and technical scope of the present disclosure. In addition, it should be noted that the drawings disclosed herein are not limited and may be embodied in other forms. Furthermore, throughout the specification, the same reference numerals refer to the same components, and it should be noted that like components are indicated by like reference numerals throughout the drawings wherever possible.

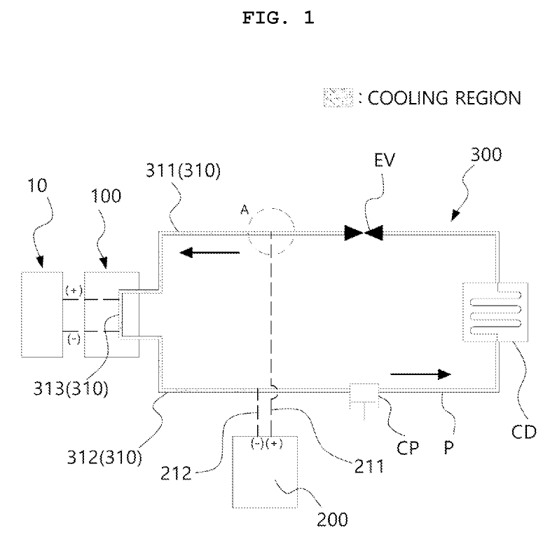

Referring to FIG. 1, a high-power charging system of the present disclosure includes a power supply apparatus 200, a connector 100, and a cooling system 300.

The power supply apparatus 200 is configured to supply direct current electricity for rapid charging of an electric vehicle 10, and is provided with power cables 211 and 212 including the positive electrode cable 211 and the negative electrode cable 212. In the present disclosure, the power cables 211 and 212 may be provided in the form of bare wires, and metal cables formed of such as copper, aluminum, an alloy thereof, and so on without an insulator such as a separate covering may be provided as the power cables 211 and 212. The bare wire may be provided as a solid wire or a stranded wire. Furthermore, since there is no covering, the bare wire is directly exposed to the environment, but the overall volume may be reduced and a relatively light-weight charging system is capable of being realized.

The connector 100 is configured to connect the electric vehicle 10 and the charging system to each other, and is configured to connect a power supply terminal 110 provided on the connector 100 and a charging terminal 11 of the electric vehicle 10 to each other, thereby charging the electric vehicle 10 by supplying electricity supplied by the power cables 211 and 212 of the power supply apparatus 200.

The cooling system 300 is provided for thermal management of the charging system, such as reducing electric resistance by removing Joule heat generated when electricity is transferred through the power cables 211 and 212 and the power supply terminal 110. The cooling system 300 is provided as a closed loop forming a cooling cycle including a compressor CP, a condenser CD, an expansion valve EV, and cooling parts 310, 311, and 312, and an insulation refrigerant flows within the closed loop and circulates throughout the entire cooling cycle.

Referring to the enlarged view in FIG. 1, at this time, the cooling part 310 may be provided as a cooling pipe in which the insulation refrigerant flows and which directly cools the power cables 211 and 212. The power cables 211 and 212 in the form of bare wires are inserted into the cooling part 310, and are exposed to the insulation refrigerant environment at a low temperature. The metal bare wire without the covering is in direct contact with the refrigerant flowing in the direction of the arrow inside the cooling pipe, so that heat-exchange is performed rapidly and efficiently.

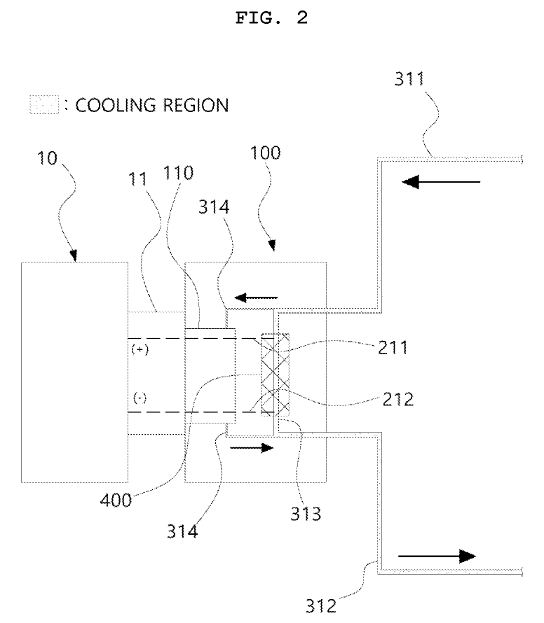

As illustrated in FIG. 1 and FIG. 2, the cooling part 310 may include a positive electrode cable cooling pipe 311 configured to cool the positive electrode cable 211, a negative electrode cable cooling pipe 312 configured to cool the negative electrode cable 212, and a connection pipe 313 that connects the positive electrode cable cooling pipe 311 and the negative electrode cable cooling pipe 312 to each other, and the refrigerant flow in the cooling part 310 by moving each of the pipes sequentially in the order of the positive electrode cable cooling pipe 311, the connection pipe 313, and the negative electrode cable cooling pipe 312 or in the reverse order.

The positive electrode cable cooling pipe 311, the connection pipe 313, and the negative electrode cable cooling pipe 312 are parts of a refrigerant pipe P having the same material as a copper pipe provided so that the refrigerant flows in the entire cooling system 300 such as the compressor CP, the condenser CD, the expansion valve EV, and so on, and may be provided as a heat-exchange material as the same metal forming the refrigerant pipe P. That is, a structure in which the positive electrode cable 211 and the negative electrode cable 212 are directly inserted into a partial section of the refrigerant pipe is provided, so that the refrigerant pipe in the form in which the positive electrode cable 211 and the negative electrode cable 212 are embedded in the refrigerant pipe are provided to the connector 100, thereby realizing the thermal treatment. By using the connected refrigerant pipe as the cooling part 310, the cooling system 300 is easily provided. Furthermore, since there is no separate bonding part or a connection tool, the risk of leakage of the refrigerant may be reduced.

At this time, in order to maintain a low temperature of the refrigerant as much as possible so as to increase the efficiency of cooling, a configuration for heat insulation, such as an external covering, may be additionally provided on at least a part of the cooling part 310.

Meanwhile, at least a part of the positive electrode cable cooling pipe 311, the connection pipe 313, and the negative electrode cable cooling pipe 312 may be formed of a heat insulating material having a thermal conductivity relatively lower than that of the refrigerant pipe such as a metal that allows another configuration in the cooling system 300 to flow. For example, a polymer material pipe may be used as the heat insulating material. In this case, a material of the refrigerant pipe forming the closed loop of the cooling cycle and so on is changed at a section where the positive electrode cable 211 and the negative electrode cable 212 are inserted inside the cooling part 310 and the heat-exchange is realized. To this end, a separate bonding part or a separate connection tool may be provided.

Meanwhile, the positive electrode cable cooling pipe 311, the connection pipe 313, and the negative electrode cable cooling pipe 312 may be formed in tube shapes, and may be provided in various shapes such as circular shapes or rectangular shapes with different diameters considering cooling capacity, efficiency, and so on.

In the present disclosure, in order to prevent electrical short circuit due to condensation that may occur due to the refrigerant at the low temperature, a refrigerant leakage, and so on, an insulation part 400 is included at least one part before or after the refrigerant flows the cooling part 310 through the closed loop that connects the compressor CP, the condenser CD, the expansion valve EV, and the cooling part 310. For example, as illustrated in FIG. 1, the insulation part 400 may be provided at two regions which are a region before the positive electrode cable 211 is inserted into the cooling part 310 and a region before the negative electrode cable 212 is inserted into the cooling part 310, and the insulation part 400 may be provided such that the insulation part 400 has a hollow structure so that the refrigerant pipe is embedded inside the insulation part 400.

The insulation part 400 is a non-conductive material, and may include at least one selected from the group consisting of perfluoroalkoxy (PFA), fluorinated ethylene (FEP), poly Tetra Fluoro Ethylene (PTFE), Poly Ether Ketone (PEEK), high heat-resistant plastic, nylon, silicone, and urethane. Particularly, in order to maintain the electrical insulation function even in a low temperature environment due to the refrigerant, Poly Ether Ketone (PEEK) may be used. Poly Ether Ketone (PEEK) is a semi-crystalline thermoplastic that has excellent chemical resistance, excellent mechanical strength, low moisture absorption, robust fire resistance, and excellent dimensional stability over wide temperature range.

In the present disclosure, in order to prevent an electrical short circuit that may occur due to the condensation of the refrigerant at the low temperature or due to the leakage of the refrigerant, the connection pipe 313 of the cooling part 310 may include the insulation part 400. For example, as illustrated in FIG. 2, the insulation part 400 having the hollow structure may be disposed on an outer surface of the connection pipe 313 that connects the positive electrode cable cooling pipe 311 and the negative electrode cable cooling pipe 312 to each other. As another embodiment, the insulation part 400 may be provided such that a non-conductive material is used as the connection pipe 313.

In the present disclosure, a main objective of the cooling part 310 is to realize a direct heat-exchange with the power cables 211 and 212, but a sub-cooling pipe 314 may be further provided by bypassing a part of the cooling part 310. The sub-cooling pipe 314 may be provided selectively on the positive electrode cable cooling pipe 311, the connection pipe 313, and the negative electrode cable cooling pipe 312 as required, and may be provided as a small cooling pipe in which a part of the refrigerant can flow therethrough. Furthermore, the sub-cooling pipe 314 may serve to perform the thermal management of the power supply terminal 110, the thermal management being capable of being required at the connector 100. In order to reduce heat generated as the power supply terminal 110 is also connected to the charging terminal 11 of the electric vehicle 10 during rapid charging, the power supply terminal may exchange heat with the sub-cooling pipe 314. Unlike the power cables 211 and 212 of the present disclosure, the sub-cooling tube 314 may be provided adjacent to the power supply terminal 110 so that indirect heat-exchange with the refrigerant is realized. The refrigerant flowing through the sub-cooling pipe 314 is recovered to the cooling system 300 of the closed loop.

In the present disclosure, in order to provide a cryogenic cooling environment, the refrigerant may be a cryogenic cooling refrigerant, and may be selected from one of R134a, R32, R410A, R404A, R507, 1234yf, or 1234ze. In the cooling system 300, the refrigerant which is supplied to the cooling part 310 and which is in a liquid state at a low temperature and a low pressure after passing through the expansion valve may be phase-changed to a gaseous state at a low temperature and a low pressure by exchanging heat with the power cables 211 and 212 from the cooling part 310. By using an evaporative heat of the refrigerant, there is an effect that the cooling efficiency is increased.

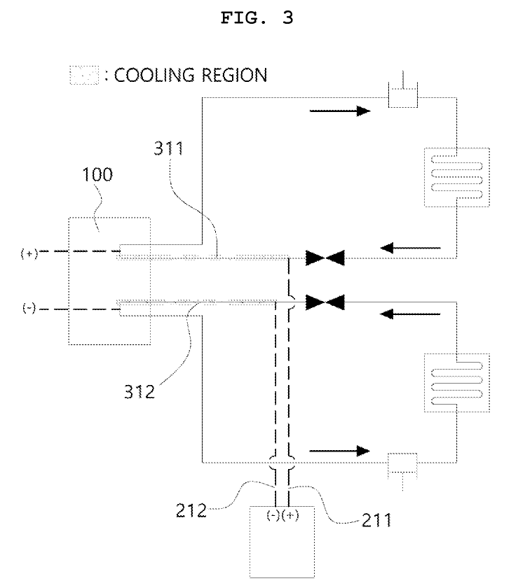

In FIG. 3, a cooling connection part 500 configured to allow the refrigerant flowing inside the refrigerant pipe P to meet the positive electrode cable 211 or the negative electrode cable 212 is illustrated.

The cooling connection part 500 is provided with a power supply part 510 to which a positive electrode power source or a negative electrode power source is connected, and is provided with a refrigerant inlet part 530 for introducing the refrigerant flowing inside the refrigerant pipe P. The introduced refrigerant flows along a hollow space inside the cooling connection part 500, and is met with the positive electrode cable cooling pipe 311 or the negative electrode cable cooling pipe 312. The positive electrode cable 211 or the negative electrode cable 212 provided inside the cooling connection part 500 is electrically joined to a power joining part 520 provided on a first side of the cooling connection part 500, and is electrically connected to the power supply part 510 provided from the outside. The power joining part 520 and either the positive electrode cable 211 or the negative electrode cable 212 may be electrically connected to each other through an external strong pressing. A cap 540 is provided so as to prevent the leakage of the refrigerant.

Meanwhile, as illustrated in FIG. 3, even though the insulation refrigerant is used, an electric current flowing along the positive electrode cable or the negative electrode cable may backflow to a refrigerant flow line along the refrigerant pipe (copper pipe). In order to prevent this situation, an insulation part 315 may be provided on a first end of the refrigerant pipe. A portion of the refrigerant pipe (copper pipe) may be cut and may be joined to both ends of the insulation part 315 in a screw coupling manner and so on.

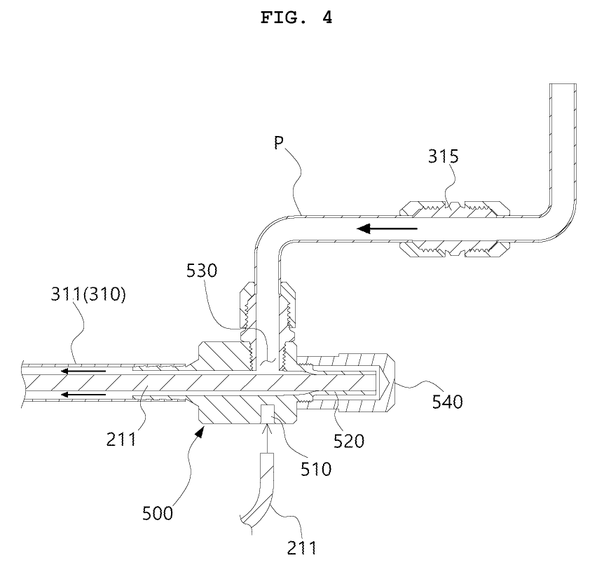

Meanwhile, referring to FIG. 4, it is possible to increase the cooling performance by configuring the cooling system 300 as at least two cooling systems 300. Particularly, the closed loop of the cooling cycle may be configured such that different cooling systems 300 respectively cool the positive electrode cable 211 and the negative electrode cable 212. In this case, not only the cooling performance is increased, but also the possibility of the occurrence of the short circuit due to the condensation caused by a temperature difference, the leakage of the refrigerant, and so on may be significantly reduced, and there is an effect that a separate insulation part 400 is not required to be provided.

What is claimed is:

1. A high-power charging system comprising:
a connector for charging an electric vehicle;
a power supply apparatus comprising a power cable for supplying electricity to the connector; and
a cooling system comprising a cooling part in which a refrigerant that cools the power cable flows,
wherein the power cable is inserted inside the cooling part, and is exposed to a refrigerant environment at a low temperature.

2. The high-power charging system of claim 1, wherein the power cable is provided in a form of a bare wire, and exchanges heat with the refrigerant by being in direct contact with the refrigerant.

3. The high-power charging system of claim 2, wherein the cooling system is a closed loop connecting a compressor, a condenser, an expansion valve, and the cooling part to each other, and comprises an insulation part at at least one place before or after where the refrigerant flows into the cooling part.

4. The high-power charging system of claim 2, wherein the power cable comprises a positive electrode cable and a negative electrode cable,
wherein the cooling part comprises:
a positive electrode cable cooling pipe configured to cool the positive electrode cable;
a negative electrode cable cooling pipe configured to cool the negative electrode cable; and
a connection pipe connecting the positive electrode cable cooling pipe and the negative electrode cable cooling pipe to each other, and
wherein the positive electrode cable cooling pipe and the negative electrode cable cooling pipe are parts of a refrigerant pipe in which the refrigerant flows throughout the cooling system, and are formed of a same material.

5. The high-power charging system of claim 2, wherein the power cable comprises a positive electrode cable and a negative electrode cable,
wherein the cooling part comprises:
a positive electrode cable cooling pipe configured to cool the positive electrode cable;
a negative electrode cable cooling pipe configured to cool the negative electrode cable; and
a connection pipe connecting the positive electrode cable cooling pipe and the negative electrode cable cooling pipe to each other, and
wherein each of the positive electrode cable cooling pipe and the negative electrode cable cooling pipe is formed of a heat insulation material having a thermal conductivity lower than that of a refrigerant pipe in which the refrigerant flows throughout the cooling system.

6. The high-power charging system of claim 4, wherein the connection pipe comprises an insulation part.

7. The high-power charging system of claim 5, wherein the connection pipe comprises an insulation part.

8. The high-power charging system of claim 2, wherein the power cable comprises a positive electrode cable and a negative electrode cable, and the cooling system is configured as a plurality of cooling systems configured to respectively cool the positive electrode cable and the negative electrode cable.

9. The high-power charging system of claim 2, wherein the connector comprises a power supply terminal configured to be connected to a charging terminal of the electric vehicle, and the cooling part comprises a sub-cooling pipe configured to bypass a flow of a part of the refrigerant so as to cool the power supply terminal.

10. The high-power charging system of claim 2, wherein the refrigerant is a refrigerant for cryogenic cooling, is selected from one of R134a, R32, R410A, R404A, R507, 1234yf, and 1234ze, and undergoes a liquid-to-vapor phase transformation through heat-exchange in the cooling part.
